(19) United States
(12) Patent Application Publication
(10) Pub. No.: US 2026/0090323 A1
(43) Pub. Date: Mar. 26, 2026

(54) MAPPING APPARATUS, SUBSTRATE PROCESSING APPARATUS, MAPPING METHOD, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Akinari HAYASHI, Toyama (JP); Shigenori TEZUKA, Toyama (JP); Jin SHIBATA, Toyama (JP); Toshiharu KUROSAWA, Toyama (JP)

(73) Assignee: KOKUSAI ELECTRIC CORPORATION, Tokyo (JP)

(21) Appl. No.: 19/297,074

(22) Filed: Aug. 12, 2025

(30) Foreign Application Priority Data
Sep. 25, 2024 (JP) 2024-165759

(51) Int. Cl. H01L 21/67; G01B 11/06; G01N 21/59; H01L 21/687

(52) U.S. Cl. CPC H10P 72/0611; G01B 11/06; G01N 21/59; H10P 72/7602; G01N 2201/06113

(57) ABSTRACT

There is provided a technique that includes: a plurality of light emitters arranged to be capable of emitting reference light onto each of a plurality of substrates arranged at a predetermined interval; a plurality of light receivers disposed to face the plurality of light emitters, each of the plurality of light receivers being capable of detecting light transmitted through a corresponding substrate among the plurality of substrates; a driver configured to relatively move the plurality of substrates so that the plurality of substrates pass through a plurality of optical axes connecting the plurality of light emitters and the corresponding plurality of light receivers respectively; a determiner configured to perform a predetermined determination based on a light reception intensity of each of the plurality of light receivers; and a discriminator configured to discriminate a material of each of the plurality of substrates based on a determination result from the determiner.

### CROSS-REFERENCE TO RELATED APPLICATION

This application is based upon and claims the benefit of priority from Japanese Patent Application No. 2024-165759, filed on Sep. 25, 2024, the entire contents of which are incorporated herein by reference.

### TECHNICAL FIELD

The present disclosure relates to a mapping apparatus, a substrate processing apparatus, a mapping method, a method of manufacturing a semiconductor device, and a recording medium.

### BACKGROUND

In the related art, there is a case where a loading (storage) state of wafers within a wafer cassette is checked (wafer mapping) in a cassette receiving platform on which the wafer cassette transported by an external transporter or by a person is placed.

There are cases where wafers made of different materials, such as silicon (Si) and silicon carbide (SiC), are introduced into a substrate processing apparatus, either alone or in combination. For example, a wafer made of an incorrect material may be delivered to the apparatus, and this needs to be detected.

### SUMMARY

The present disclosure provides a technique capable of discriminating materials of wafers.

According to embodiments of the present disclosure, there is provided a technique that includes: a plurality of light emitters arranged to be capable of emitting reference light onto each of a plurality of substrates arranged at a predetermined interval; a plurality of light receivers disposed to face the plurality of light emitters, each of the plurality of light receivers being capable of detecting light transmitted through a corresponding substrate among the plurality of substrates; a driver configured to relatively move the plurality of substrates so that the plurality of substrates pass through a plurality of optical axes connecting the plurality of light emitters and the corresponding plurality of light receivers respectively; a determiner configured to perform a predetermined determination based on a light reception intensity of each of the plurality of light receivers; and a discriminator configured to discriminate a material of each of the plurality of substrates based on a determination result from the determiner.

### BRIEF DESCRIPTION OF DRAWINGS

The accompanying drawings, which are incorporated in and constitute a part of the specification, illustrate embodiments of the present disclosure.

FIG. 1 is a diagram illustrating a substrate processing apparatus.

FIG. 2 is a perspective view of a cassette receiving unit.

FIG. 3 is a perspective view of a comb-shaped sensor and a wafer posture aligner provided on a cassette stage.

FIG. 4 is a diagram illustrating a configuration of a mapping apparatus according to one embodiment.

FIG. 5 is a diagram illustrating a configuration of a mapping apparatus according to another embodiment.

FIG. 6 is a configuration diagram illustrating a control system for wafer mapping using a laser sensor.

FIG. 7 is a schematic perspective view of a wafer transferrer, and is a diagram illustrating detection of substrate abnormalities (cracks) within a boat.

FIG. 8 is a diagram illustrating a processing flow of a substrate processing method.

FIG. 9A is a diagram illustrating an example of analog data for a light quantity detected by a photosensor in a normal substrate holding state in the substrate processing apparatus. FIG. 9B is a diagram illustrating an example of digital data for the light quantity.

FIG. 10 is a diagram illustrating an example of wafer thickness correction in crack detection.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

Hereinafter, one embodiment of the present disclosure is described with reference to the accompanying drawings. In addition, the drawings used in the following description are schematic, and dimensional relationships between respective elements, proportions of the respective elements, and others illustrated in the drawings may not match with those in reality. Further, the dimensional relationships between respective elements and the proportions of respective elements may not match among multiple drawings. Further, the same reference numerals are given to substantially the same elements among the multiple drawings, and a description of each element is given in the drawing in which that element first appears, and in subsequent drawings, the description is omitted unless particularly needed. Unless otherwise mentioned in the present disclosure, each element is not limited to one and may be present in plurality.

### (1) Substrate Processing Apparatus

In the present embodiment, a substrate processing apparatus (hereinafter also simply referred to as the “processing apparatus”) is configured, for example, as a semiconductor manufacturing apparatus that performs processing steps in a method of manufacturing a semiconductor device.

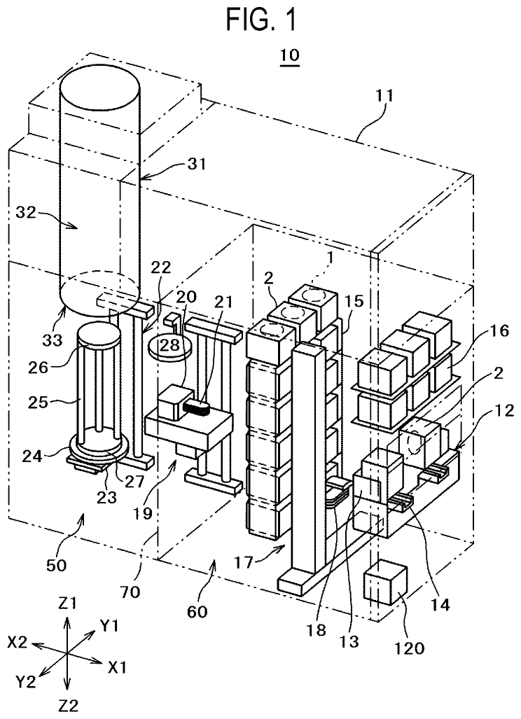

As illustrated in FIG. 1, the processing apparatus 10 according to the embodiment includes a housing 11, and the interior of the housing 11 is divided into a transfer chamber 50 and a cassette holding chamber 60 by a partition wall 70. A cassette receiving unit 12 is provided at a front surface of the housing 11, i.e., a front surface (X1 side) of the cassette holding chamber 60. An X1-X2 direction is a front-rear direction of the processing apparatus 10, a Y2-Y1 direction is a left-right direction, and a Z1-Z2 direction is an up-down direction. The cassette receiving unit 12 includes a cassette stage device 13, which may place thereon one or two cassettes 2 that serve as substrate containers and also serve as carriers for wafers 1 serving as substrates. Two wafer posture aligners 14 are provided below the cassette stage device 13. The cassette 2 is also referred to as an open cassette. The cassette receiving unit 12 is also referred to as a cassette loader, load port, or I/O port. A placement table 44 (described later) of the cassette stage device 13 receives the cassette 2, transported by an external transporter (not illustrated), in a vertical posture. Herein, the vertical posture refers to a state where the wafers 1 stored in the cassette 2 are oriented vertically.

The wafer posture aligner 14 aligns postures of the wafers 1 stored in the cassette 2 in the vertical posture such that notches of the wafers 1 are aligned. The placement table 44 is configured to be rotatable by 90 degrees between the vertical posture and a horizontal posture of the cassette 2. Herein, the horizontal posture refers to a state where the wafers 1 stored in the cassette 2 are oriented horizontally and an access opening of the cassette 2 faces an X2 direction. In the cassette holding chamber 60, a cassette shelf 15 is provided to face the cassette receiving unit 12 and a spare cassette shelf 16 is provided above the cassette receiving unit 12.

A cassette transporter 17 is provided between the cassette receiving unit 12 and the cassette shelf 15. The cassette transporter 17 includes a robot arm 18 capable of reciprocating the cassette in the horizontal posture in the front-rear direction (X1-X2 direction), and the robot arm 18 itself is configured to be capable of moving horizontally and vertically. The robot arm 18 transports the horizontal-posture cassette 2 on the cassette stage device 13 to the cassette shelf 15 or the spare cassette shelf 16 through reciprocating (forward and backward), vertical, and horizontal movements. The cassette shelf 15 and the spare cassette shelf 16 function as buffers that store the loaded wafers 1 in a state where they are still loaded in the cassette 2 used during loading into the processing apparatus 10 until needed.

The transfer chamber 50 is provided with, e.g., a wafer transferrer 19 and a boat elevator 22. The wafer transferrer (transfer device) 19 is provided to be rotatable and vertically movable at a rear side (X2 side) of the cassette shelf 15, and transfers the wafers 1 stored in the cassette 2 either collectively or one by one onto a boat 25 serving as a substrate support. The wafer transferrer 19 includes, e.g., a reciprocator 20 that reciprocally moves a plurality of wafer holding plates 21, and may access the cassette 2 facing thereto within the cassette shelf 15 through an opening in the partition wall 70. The wafer holding plate 21 is also referred to as an end effector, tweezer, or fork.

The boat elevator 22 is provided at a rear side (X2 side) of the wafer transferrer 19, and holds a seal cap 24 via an arm 23 in a vertically movable manner.

The processing apparatus 10 includes a reaction tube (process tube or process container) 31 made of a highly heat-resistant material such as quartz or SiC, and the reaction tube 31 is disposed vertically with a tube axis aligned in a vertical direction. A hollow cylindrical interior of the reaction tube 31 forms a process chamber 32 in which a plurality of wafers 1 are accommodated, and a lower end of the reaction tube 31 opens to the transfer chamber 50, forming a furnace opening 33 for an entrance and exit of the wafers 1. The furnace opening 33 is closed by the seal cap 24.

The seal cap 24 that closes the furnace opening 33 comes into contact from below in the vertical direction with a lower end surface of the reaction tube 31. The seal cap 24 is formed in a disk shape and is configured to be vertically movable by the boat elevator 22 provided outside the reaction tube 31. Further, a furnace opening shutter 28 may be provided to seal the furnace opening 33 when the seal cap 24 is moved to a lower end position.

The boat 25 for holding the wafers 1 is supported vertically on top of the seal cap 24. The boat 25 includes a pair of upper and lower end plates 26 and 27, and a plurality of (three in the present embodiment) vertically disposed holding members (pillars) spanned between the two end plates 26 and 27. Each holding member includes a plurality of holding grooves that are equidistantly disposed in a longitudinal direction, with the grooves recessed and facing each other. Outer peripheral edges of the wafers 1 are inserted respectively into the plurality of holding grooves of each holding member, so that the wafers 1 are held horizontally and aligned concentrically with one another within the boat 25.

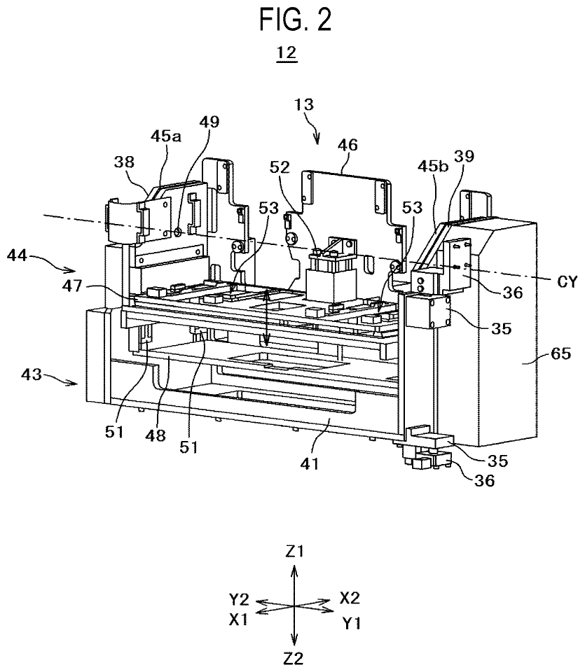

The cassette receiving unit 12 is described with reference to FIG. 2.

A front plate 41 toward an X1 direction and a rear plate (not illustrated) toward the X2 direction are fixed to lower portions of a left plate 38 toward a Y2 direction and a right plate 39 toward a Y1 direction to form a frame 43, and a lower portion of the frame 43 is formed in a square tubular shape.

Two hinge members 35 are fixed at upper and lower positions to an outer surface of the right plate 39 at a lateral end on the front plate 41. Two hinge members 36 are fixed to a front surface side (X1 direction side) of the housing 11 illustrated in FIG. 1 and are connected to the corresponding hinge members 35. The cassette stage device 13 is supported rotatably relative to the housing 11 by the hinge members 35, which are rotatable around an axis in the Z1-Z2 direction.

A rotation shaft 49 supports the placement table 44 on the left plate 38 and the right plate 39 so as to be rotatable around a CY axis. The placement table 44 includes a pair of rotation plates 45a and 45b, an internal receiving stage 46, an external receiving stage 47, and a lower plate 48. The rotation plates 45a and 45b are fixed respectively to the rotation shaft 49 on the CY axis, and are rigidly connected to each other by the lower plate 48. The placement table 44 is rotatable around the rotation shaft 49. The internal receiving stage 46 is fixed to the rotation plates 45a and 45b and/or the lower plate 48. The external receiving stage 47 is attached to the rotation plates 45a and 45b, which are in a horizontal state, via a plurality of guides 51 that allow a movement solely in one direction so that the cassette in the vertical posture is movable in the up-down direction. An air cylinder 52 serving as a driver is installed between the internal receiving stage 46 and the external receiving stage 47, and drives the external receiving stage 47 up and down. Two cassettes 2 may be placed on the internal receiving stage 46 and the external receiving stage 47.

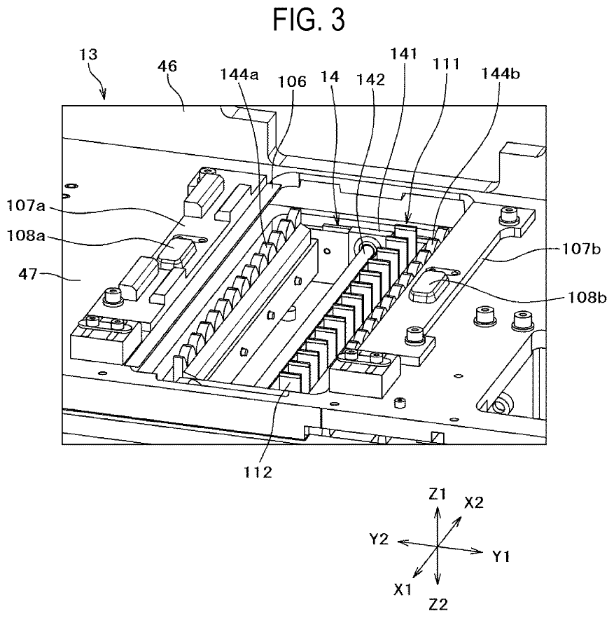

Two wafer alignment holes 53 are formed at the external receiving stage 47 in a predetermined interval. The wafer posture aligners 14 are installed at the lower plate 48 below the wafer alignment holes 53. The external receiving stage 47 is provided with cassette guides, which extend in the X1-X2 direction on both sides for each wafer alignment hole 53, and strain gauges (load cells) 108a and 108b are installed above them (see FIG. 3). The strain gauges 108a and 108b are disposed near centers of two bottom sides of the cassette so that they cooperate to bear a total weight of one cassette 2, which accommodates the wafers 1 and is placed on the external receiving stage 47. Further, a belt-shaped reflector 106 is provided on one side of the wafer alignment hole 53 to extend in the X1-X2 direction.

A driver 65 for rotating the rotation shaft 49 is attached to the outer surface of the right plate 39. The driver 65 includes, for example, an AC servomotor, a worm gear box, a position sensor and the like, and is configured to be capable of rotating the cassette 2 on the placement table 44 by 90 degrees between the horizontal posture and the vertical posture.

An example of the wafer posture aligner 14 is described with reference to FIG. 3.

The wafer posture aligner 14 includes a support stand 141, a roller 142 horizontally and rotatably suspended by the support stand 141, a rotation drive device (not illustrated) for rotating the roller 142, and a pair of wafer guides 144a and 144b. The roller 142 extends in an alignment direction (X1-X2 direction) of the group of wafers 1 stored in the cassette 2. The pair of wafer guides 144a and 144b maintain the wafers 1 at a predetermined height so that the wafers 1 idle when the notches formed in the wafers 1 are fitted onto the roller 142. Since the air cylinder 52 moves the external receiving stage 47 up and down, the wafer posture aligner 14 is vertically movable relative to the cassette 2 placed on the placement table 44. During an alignment operation, the wafer posture aligner 14 is raised so that a plurality of wafers 1 in an interior of the cassette 2 placed on the cassette stage device 13 come into contact with the roller 142. The wafer posture aligner 14 is configured to align the notches of the plurality of wafers 1 at a certain location by rotating the wafers 1 in the same direction using the roller 142. In other words, notch alignment is mechanically performed by rotating the roller 142 so that the wafers 1 rotate more than once and the rotation is restricted and the roller 142 idles when the notches reach the roller 142.

Further, the wafer posture aligner 14 is provided with a comb-shaped sensor 111, which detects presence or absence of each of the wafers 1 made of a predetermined material within the cassette 2 before the wafer posture alignment (when the wafers 1 are in a vertical state) and which is installed so as not to mechanically interfere with the cassette 2 placed on the cassette stage device 13. The comb-shaped sensor 111 is fixed to the support stand 141 between the roller 142 and the wafer guide 144b on a Y1 side, and is configured to be movable up and down relative to the cassette 2 along with the wafer posture aligner 14. This allows the comb-shaped sensor 111 to move between a detection position for detecting the wafers and a retracted position. Wafer mapping by the comb-shaped sensor 111 is performed in a posture of the cassette 2 different from when performing wafer mapping by a laser sensor 101, which is described later. Thus, it is possible to install the comb-shaped sensor 111 at a location different from that of the laser sensor 101. The comb-shaped sensor 111 is configured by installing a light emitter 113 and a light receiver 114, which are described later, on a plurality of protrusions arranged at a predetermined interval on a comb-shaped frame 112, respectively.

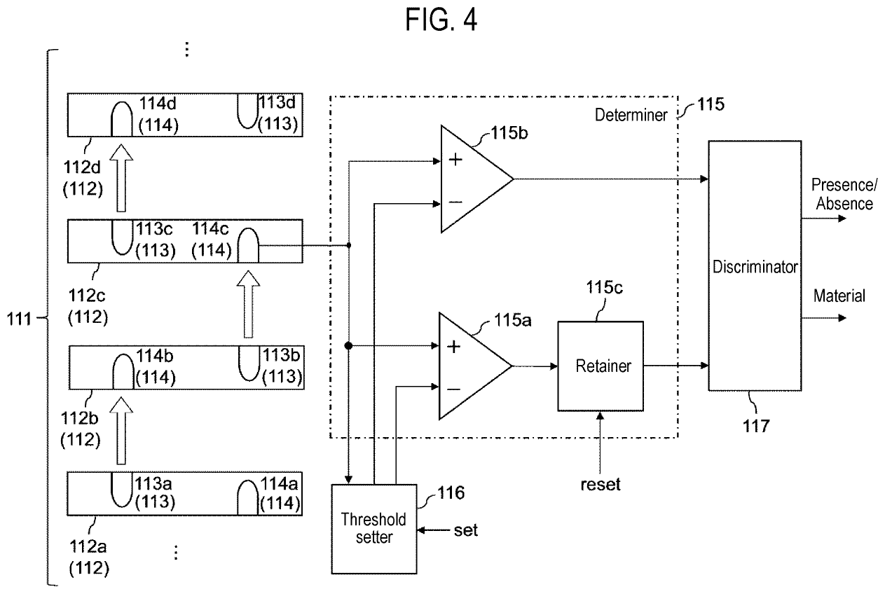

A configuration example of a first mapping apparatus is described with reference to FIG. 4. The first mapping apparatus includes the comb-shaped sensor 111, a determiner 115, a threshold setter 116, and a discriminator 117.

The comb-shaped sensor 111 is formed by arranging a plurality of pairs of transmission-type photoelectric sensors, each of which is composed of the light emitter 113 and the light receiver 114, in an arrangement direction (X1-X2 direction) of the wafers 1 in a comb shape, the number of the pairs corresponding to the number of wafers 1 that may be accommodated in the cassette 2. The opposing light emitter 113 (e.g., light emitter 113a) and light receiver 114 (e.g., light receiver 114b) (disposed to face each other) detect the presence or absence of each wafer 1 on an optical path therebetween. The light emitter 113 is formed, for example, of a light emitting diode that emits near-infrared or visible light, and the light receiver 114 is formed, for example, of a phototransistor. Protrusions 112a to 112d of the comb-shaped frame 112 integrally accommodate light emitters 113a to 113d and light receivers 114a to 114d, respectively. In other words, the plurality of light emitters 113 are arranged to be capable of emitting reference light to each of a plurality of wafers 1 arranged at a predetermined interval. The plurality of light receivers 114 are arranged to face the plurality of light emitters 113, and each of them is capable of detecting light transmitted through the corresponding wafer 1.

The comb-shaped sensor 111 is configured to be movable relative to the cassette 2 on the cassette stage device 13 between the detection position where it may detect a substrate and the retracted position. In this example, the detection position corresponds to a state where the external receiving stage 47 is lowered, and at this time, the light emitter 113 is disposed on one side of an arrangement region for each wafer 1, specifically, a storage region (slot) for each wafer 1 within the cassette 2 in this example. The light receiver 114 is disposed on the optical path of light emitted from the light emitter 113 so as to face the light emitter 113 via the storage region for the wafer 1. In other words, at the detection position, the light emitter 113 and the light receiver 114 are disposed such that, a light emitting surface of the light emitter 113 faces a first surface of the wafer 1, and a light receiving surface of the light receiver 114 faces a second surface of the wafer 1 opposite to the first surface. An optical axis connecting the light emitter 113 and the light receiver 114 intersects the wafer 1 at a location sufficiently inside an end of the wafer 1. On the other hand, at the retracted position, the optical axis passes sufficiently outside the end of the wafer 1. The air cylinder 52 that moves the cassette 2 relative to the comb-shaped sensor 111 and a main controller 120 that controls the air cylinder 52 may be included in the first mapping apparatus.

The comb-shaped sensor 111 is a transmission-type sensor. For example, in the case of the wafer 1 that is not light-transmissive, the light receiver 114 receives (detects) light (reference light) emitted from the light emitter 113 when the wafer 1 is absent, and does not receive the light emitted from the light emitter 113 when the wafer 1 is present. This enables detection of the presence or absence of the wafer 1. Herein, a non-transmissive wafer exhibits a transmittance close to 0% for the reference light (e.g., visible light), and is, for example, a Si wafer. However, in addition to the Si wafer, the wafer 1 may also be a transparent wafer (e.g., a quartz wafer or SiC wafer). Herein, a transmittance of a quartz wafer is about 95%, and a transmittance of a single crystal SiC wafer is about 30% to 70%.

The first mapping apparatus performs determination of the presence or absence of a non-transmissive wafer (e.g., Si wafer) and a transparent wafer (e.g., SiC wafer) and a wafer type by the determiner 115, threshold setter 116, and discriminator 117, based on a detection result of the comb-shaped sensor 111.

The determiner 115 performs a predetermined determination based on a light reception intensity of each of the plurality of light receivers 114. The determiner 115 includes a first comparator 115a, a second comparator 115b, and a retainer 115c for each light receiver 114. In FIG. 4, the determiner 115 connected to the light receiver 114c is illustrated.

The first comparator 115a includes a non-inverting terminal to which an output of the light receiver 114 is input, and an inverting terminal to which a first threshold set by the threshold setter 116 is input. The first comparator 115a compares the light reception intensity of the light receiver 114 with the first threshold. If the light reception intensity of the light receiver 114 is greater than the first threshold, the first comparator 115a outputs a high level, and if the light reception intensity of the light receiver 114 is equal to or less than the first threshold, the first comparator 115a outputs a low level. The high level may also be referred to as “H” or “1” (hereinafter referred to as “H”). The low level may also be referred to as “L” or “0” (hereinafter referred to as “L”). The first comparator 115a corresponds to a first mode, which is described later.

The second comparator 115b includes a non-inverting terminal to which an output of the light receiver 114 is input, and an inverting terminal to which a second threshold set by the threshold setter 116 is input. The second comparator 115b compares the light reception intensity of the light receiver 114 with the second threshold. If the light reception intensity of the light receiver 114 is greater than the second threshold, the second comparator 115b outputs “H,” and if the light reception intensity of the light receiver 114 is equal to or less than the second threshold, the second comparator 115b outputs “L.” The second comparator 115b corresponds to a second mode, which is described later.

The retainer 115c is configured, for example, as a negative logic input/output RS flip-flop. An output of the retainer 115c is reset to a false state (“H”) when a reset signal becomes “L.” After that, when an input from the first comparator 115a becomes “L,” the retainer 115c continues to output a true state (“L”). The reset signal is supplied from the main controller 120 or the discriminator 117.

When a set signal becomes “H,” the threshold setter 116 possesses, for example, 70% and 30% values of the light reception intensity of the light receiver 114 at that time as the first threshold and the second threshold, and continues to output them to the first comparator 115a and the second comparator 115b, respectively. The set signal is supplied from the main controller 120.

The discriminator 117 discriminates the presence or absence of each of the plurality of wafers 1 and of a material (type) of each of the plurality of wafers 1 based on a determination result of the determiner 115. The discriminator 117 may also be configured as one function of the main controller 120.

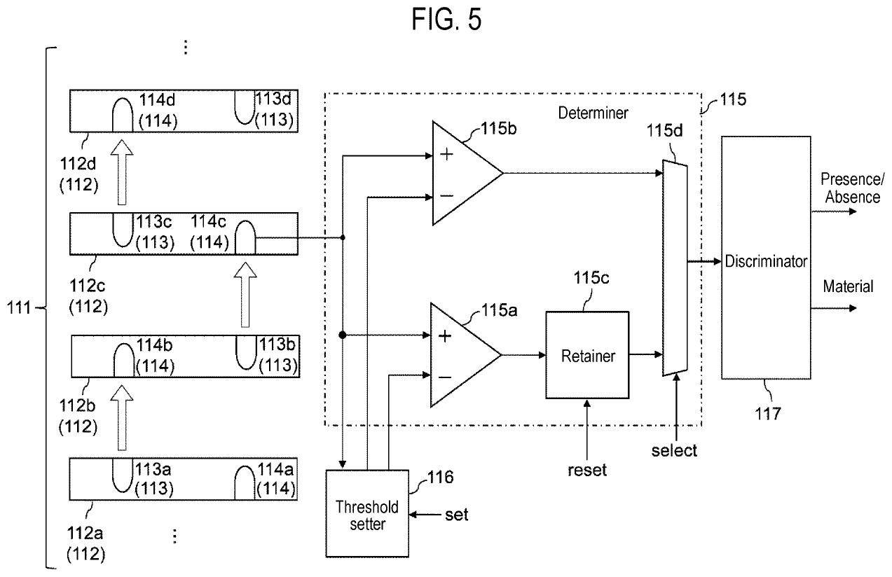

As illustrated in FIG. 5, the determiner 115 may also be installed with a selector 115d that selectively (alternatively) outputs an output of the retainer 115c and an output of the second comparator 115b. The selector 115d selects the outputs of the retainer 115c and the second comparator 115b in response to a select signal. The select signal is supplied from the main controller 120 or the discriminator 117. This allows the discriminator 117 to sequentially select and receive outputs of the first mode and the second mode.

An operation of the first mapping apparatus is described with reference to FIGS. 4 and 5. The determiner 115 of the first mapping apparatus operates in a confirmation mode, the first mode, and the second mode. The determiner 115 is configured to enable a simultaneous or an alternative operation of the first mode and the second mode. Herein, the simultaneous operation refers to an operation in which the first mode and the second mode operate simultaneously (in parallel) and the outputs of both the modes are provided either simultaneously or selectively. The alternative operation refers to an operation in which the first mode and the second mode operate non-simultaneously and solely the output of the operating mode is output. For example, switching to the second mode is made solely during a time when an edge of the wafer passes through the optical axis while the comb-shaped sensor 111 is moving from the retracted position to the detection position. Alternatively, switching from the first mode to the second mode is made while the comb-shaped sensor 111 is stationary at the detection position, that is, while a plurality of optical axes are positioned on the plurality of wafers 1, respectively.

### (Confirmation Mode)

Prior to operation, in the confirmation mode, the determiner 115 acquires, as a reference light reception intensity, the light reception intensity of each of the plurality of light receivers 114 in a state where no wafer 1 is present on the plurality of optical axes, and checks whether each reference light reception intensity is appropriate. For example, the second comparator 115b compares the light reception intensity of the light receiver 114 with a prescribed threshold. If an amount of received light is equal to or less than the prescribed threshold, an error is output due to an insufficient light input. After that, a setting of the first and second thresholds by the threshold setter 116 may also be performed in the confirmation mode.

### (First Mode)

In the first mode, it is determined whether a transparent wafer 1 is passed over each optical axis based on changes in the light reception intensity of each of the plurality of light receivers 114 when the ends of the plurality of wafers 1 pass over the plurality of optical axes. The following provides a detailed description.

First, the comb-shaped sensor 111 is disposed at the retracted position with respect to the cassette 2 on the cassette stage device 13. Further, the retainer 115c is reset.

Next, the comb-shaped sensor 111 is moved to the detection position by the air cylinder 52. Thus, the plurality of wafers 1 intersect the plurality of optical axes that connect the plurality of corresponding light emitters 113 and light receivers 114 respectively.

In the first mode, the first comparator 115a determines that the wafer 1 is passed if a maximum decrease in the light reception intensity is greater than a value (first value) obtained by multiplying the reference light reception intensity by a first coefficient less than 1. Herein, the first threshold set by the threshold setter 116 is a value obtained by subtracting the first value from the reference light reception intensity.

If the wafer 1 is present in the cassette, the light reception intensity of the light receiver 114 changes (decreases) from the reference light reception intensity when the end of the wafer 1 passes through the optical axis, even if the wafer 1 is transparent. If the first threshold is, for example, 70% of the reference light reception intensity and the wafer 1 is a SiC wafer or Si wafer, the light reception intensity of the light receiver 114 becomes lower than the first threshold. If the light reception intensity of the light receiver 114 is lower than the first threshold, an output of the first comparator 115a becomes “L,” and the retainer 115c changes from “H” to “L” and remains at “L.”

If the wafer 1 is absent, the light reception intensity of the light receiver 114 does not change (decrease) from the reference light reception intensity. If the light reception intensity of the light receiver 114 is higher than the first threshold, the output of the first comparator 115a becomes “H,” and the retainer 115c remains at “H.” If the output of the retainer 115c is “L,” it is possible to determine that the wafer 1 is present. If the output is “H,” it is possible to determine that the wafer 1 is absent.

### (Second Mode)

In the second mode, it is determined whether a non-transmissive wafer 1 is present on each optical axis based on the light reception intensity of each of the plurality of light receivers 114 when the plurality of wafers 1 are present on the plurality of optical axes. In the first mapping apparatus illustrated in FIG. 4, it is possible to operate the second comparator 115b continuously, and a current determination result of the second mode is output to the discriminator 117 in parallel with (simultaneously with) a determination result of the first mode. The determination result of the second mode may be finalized, for example, when the comb-shaped sensor 111 reaches the detection position.

In the second mode, the second comparator 115b determines that the wafer 1 is present if the light reception intensity is lower than a value (second threshold) obtained by multiplying the reference light reception intensity by a second coefficient less than 1.

If the second threshold is, for example, 30% of the reference light reception intensity and the wafer 1 is a Si wafer, the light reception intensity of the light receiver 114 becomes lower than the second threshold, and an output of the second comparator 115b becomes “L.” If the wafer 1 is a single crystal SiC wafer, the light reception intensity of the light receiver 114 becomes equal to or higher than the second threshold, and the output of the second comparator 115b becomes “H.” This enables discrimination between a transparent wafer and a non-transmissive wafer.

The discriminator 117 discriminates the presence or absence of each of the plurality of wafers 1 and of the material of each of the plurality of wafers 1 by combining the determination results of the first mode and the second mode. The following provides a detailed description.

If the output of the retainer 115c is “H” in the first mode, the discriminator 117 discriminates that the wafer 1 is absent. If the output of the retainer 115c is “L” in the first mode and the output of the second comparator 115b is “H” in the second mode, the discriminator 117 discriminates that the wafer 1 is present and that the wafer 1 is a single crystal SiC wafer. If the output of the retainer 115c is “L” in the first mode and the output of the second comparator 115b is “L” in the second mode, the discriminator 117 discriminates that the wafer 1 is present and that the wafer 1 is a Si wafer. The discriminator 117 may complete the discrimination at the time when the determination results of the first mode and the second mode are finalized.

In the first mapping apparatus illustrated in FIG. 5, the determiner 115 switches from the first mode to the second mode in a state where the plurality of optical axes intersect the plurality of wafers 1, respectively. Accordingly, the discrimination of the presence or absence of each of the plurality of wafers 1 and of the material of each of the plurality of wafers 1 is completed through a single reciprocating movement by the air cylinder 52.

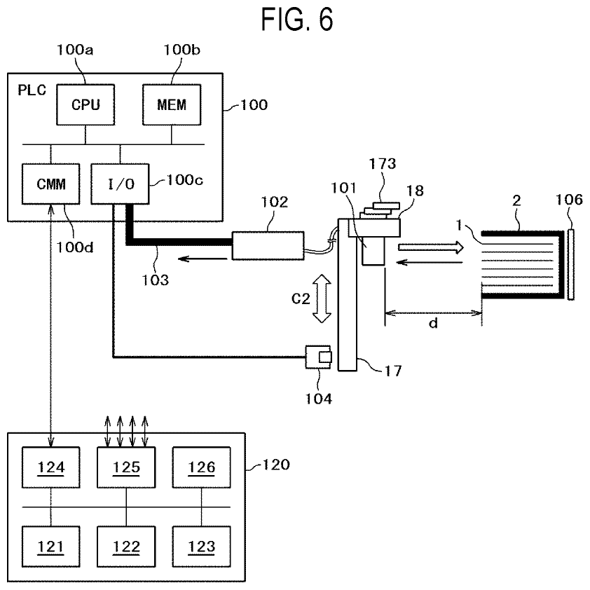

A configuration example of the cassette transporter 17 is described with reference to FIG. 6.

The cassette transporter 17 includes a driver that moves the robot arm 18 in the up-down direction (Z1-Z2 direction) and a driver that moves the above driver in the left-right direction (Y2-Y1 direction). This allows the robot arm 18 to access the cassette at any position through reciprocating, horizontal, and vertical movements. The laser sensor 101 is installed at a base of the robot arm 18 to face the X1 direction and is spaced apart from the wafer 1 by a predetermined distance d. Alternatively, the laser sensor 101 may be installed at a robot hand 173 so as to be reciprocally movable forward and backward. Further, the wafer 1 stored in the cassette 2 placed on the cassette stage device 13 is in a horizontal state. Therefore, the laser sensor 101, which is movable in an arrangement direction (Z1-Z2 direction) of the plurality of stored wafers 1 in front of the access opening of the cassette 2 through horizontal and vertical movements thereof, is used to detect thicknesses of the plurality of substrates accommodated in the cassette 2 on the internal receiving stage 46, and is also referred to as a thickness sensor.

The laser sensor 101 is a reflective-type sensor that emits laser light (reference light) substantially parallel to a main surface of the wafer 1 in the forward direction (X1 direction) and receives the laser light reflected from an end surface of the wafer 1. A trigger sensor 104 detects that the laser sensor 101 reached a reference position. The reference position is, for example, a position where a height of the laser light or a height of a center of a detection area is the same as a height of a bottom surface of the cassette 2 when the wafer is in a horizontal state.

A sub-controller 100 included in the processing apparatus 10 is described with reference to FIG. 6

The sub-controller 100 is configured as a computer equipped with a central processing unit (CPU) 100a, a memory 100b, an I/O part 100c, and a communicator 100d. The sub-controller 100 may be implemented using an industrial programmable logic controller (PLC).

Control programs and others for controlling an operation of a second mapping apparatus are stored in the memory 100b in a readable manner. The memory 100b is configured as a tangible computer-readable recording medium.

The I/O part 100c includes an analog input unit, a contact input unit, and the like which are connected to the laser sensor 101, the trigger sensor 104, and others. The communicator 100d is a device for communication with the main controller 120 included in the processing apparatus 10.

An output (current value) of the laser sensor 101 is input to the I/O part 100c via an amplifier 102 and a cable 103. Further, an output of the trigger sensor 104 of the cassette transporter 17 is also input to the I/O part 100c. The second mapping apparatus includes the sub-controller 100, laser sensor 101, reflector 106, and cassette transporter 17. Further, the laser sensor 101 is capable of detecting the respective notches of the plurality of wafers 1 accommodated in the cassette 2, which serve as orientation indication shapes, and for that reason, the laser sensor 101 is also referred to as a notch sensor. The notch is formed as a V-shaped cut in a portion of a circumference of the wafer.

The main controller 120 is described with reference to FIG. 6. The main controller 120 is configured as a computer including a CPU 121, a main memory 122, and others.

The main controller 120 is configured to control the following control targets and perform processing based on recipes via a communicator 124 or an I/O part 125 by causing the CPU 121 to read out and execute programs and recipes from an auxiliary memory 123 into the main memory 122. The control targets of the main controller 120 may include a rotational operation of the placement table 44, a vertical operation of the external receiving stage 47, an operation control of the wafer posture aligner 14, an operation control of the robot arm 18 of the cassette transporter 17, a rotational and vertical movement control of the wafer transferrer 19, a vertical operation of the boat elevator 22, the sub-controller 100, and the like. The recipes are prepared for each type of processing performed by the processing apparatus. The main controller 120 may be communicably connected to a higher-level control device (not illustrated) that manages a manufacturing process of semiconductor devices. The auxiliary memory 123 may include a recording medium such as an optical disk or USB memory.

Further, the main controller 120 is configured to be capable of storing specifications, including a material and a thickness of the wafer 1, for each use or type of the wafer 1, and of acquiring, from a higher-level device, or pre-registering the use or the type of the wafer 1 accommodated in the cassette 2 loaded into the processing apparatus 10. The specifications may include a wafer weight, and s type or a dimension of the wafer orientation indication shape. Herein, “type” refers to the concept of wafer classification, and may include any types classified by any criteria, without being limited to a specific criterion. “Use” is one of classification criteria. If classified by use, wafers may be classified into types such as “product wafer,” “dummy wafer,” and “monitor wafer.” Further, material, size, and thickness may also serve as classification criteria. Accordingly, the “type” may be subdivided into as many categories as there are combinations of classification criteria. The product wafer is a wafer on which devices that become actual products are formed. The dummy wafer is a wafer disposed above and below the product wafer disposed on the boat 25. The monitor wafer is a wafer disposed at a center or an edge of the product wafer disposed on the boat 25 and is used to inspect film formation results. The main controller 120 stores specifications such as the material, thickness, and weight of substrates for each of the product wafer, dummy wafer, and monitor wafer.

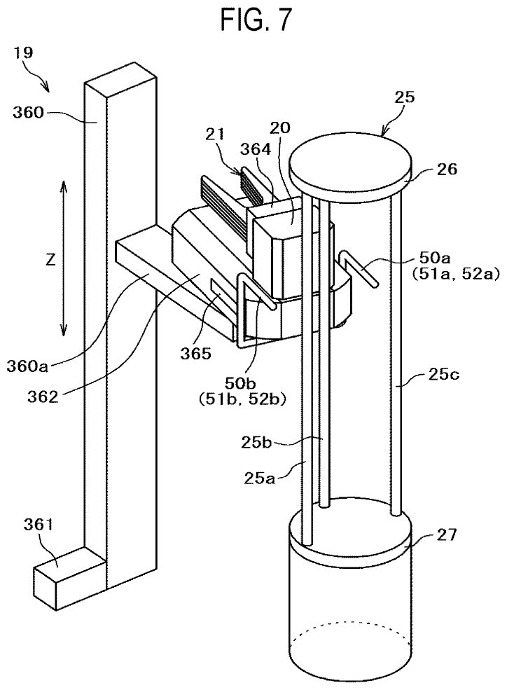

A configuration example of the wafer transferrer 19 is described with reference to FIG. 7.

The wafer transferrer 19 includes a guide 360 installed along the up-down direction (Z-axis direction), a Z-axis direction driver 361, a Y-axis rotation driver 362, an X-axis direction driver (i.e., the reciprocator 20), and a V-axis direction driver 364.

The Z-axis direction driver 361 is installed at a lower end or an upper end of the guide 360 and serves to move a mount 360a up and down (in the Z-axis direction or vertical direction) along the guide 360.

The Y-axis rotation driver 362 is installed on an upper surface of the mount 360a so as to be rotatable around the Y-axis direction, thus to support the reciprocator 20 in a manner that allows the X-axis and the Y-axis thereof to be orthogonal and to rotate the reciprocator 20 clockwise or counterclockwise in the horizontal direction (rotate around the Y-axis). A rotation range of about 180 degrees is sufficient since the cassette 2 is usually disposed between a direction of the boat 25 and an opposite direction when viewed from the Y-axis.

The reciprocator 20 is installed integrally with or within the Y-axis rotation driver 362, and serves to support the V-axis direction driver 364 and move it forward and backward in the horizontal direction (X-axis direction). In addition, the “forward” direction of the X-axis is defined as a direction in which the wafer holding plate 21 protrudes from the Y-axis rotation driver 362 to enter the boat 25 or the cassette 2.

The V-axis direction driver 364 is installed on the reciprocator 20, and is configured to horizontally support five wafer holding plates 21 while allowing the spacing thereamong to be regulated in the Z-axis direction.

Thus, it is possible for the wafer transferrer 19 to discharge the wafer 1 from the cassette 2 and move the wafer 1 in a protruding manner from the Y-axis rotation driver 362 to enter the boat 25 or the cassette 2 by using the wafer holding plate 21, thereby being charged into the boat 25. After any processing is performed on the wafer 1 in the process chamber 32, the wafer transferrer 19 is capable of discharging the wafer 1 from the boat 25 and charging it into the cassette 2 by using the wafer holding plate 21. In addition, the Y-axis rotation driver 362 is formed with an external appearance where a rotational radius thereof is equal to or slightly larger than a minimum rotational radius of the wafer holding plate 21 and the V-axis direction driver 364 around the Y-axis. For example, a length of the Y-axis rotation driver 362 in the X-axis direction is equal to or slightly longer than a combined length of the wafer holding plate 21 and the V-axis direction driver 364, and a side surface of the Y-axis rotation driver 362 at its side is parallel to the X-axis.

The wafer transferrer 19 further includes sensor rods 50a and 50b that function as arms and are installed on both side surfaces of the Y-axis rotation driver 362, and a reciprocation driver 365 that moves the sensor rods 50a and 50b in the X-axis direction.

The sensor rods 50a and 50b extend upward along both the side surfaces of the Y-axis rotation driver 362 to approximately the same height as one of the wafer holding plates 21, and are configured to bend at an approximately right angle toward a rear in the X-axis direction, which is a direction opposite to that in which the wafer holding plates 21 are mounted relative to the reciprocator 20. The sensor rods 50a and 50b hold fiber sensors 51a and 51b, which function as mapping sensors.

Light transmitting/receiving parts 52a and 52b of the fiber sensors 51a and 51b are mounted at tips of the sensor rods 50a and 50b, respectively. The fiber sensors 51a and 51b are a pair of transmission-type sensors, one of which transmits light and the other receives the light, and may be disposed such that an optical path (optical axis) formed between the light transmitting/receiving parts 52a and 52b is parallel to a tangent of the wafer 1. The fiber sensors 51a and 51b perform mapping by detecting interruptions in the optical path, which enables counting the number of wafers 1 charged into the cassette 2 or the boat 25, and detecting normal or abnormal conditions such as wafer misalignment or cracking. When the sensor rods 50a and 50b move forward, the optical axes remain aligned and horizontal. The sensor rods 50a and 50b are connected through the Y-axis rotation driver 362 so that they are interlocked with each other.

Further, the reciprocation driver 365 is disposed on one side surface of the Y-axis rotation driver 362, and supports the sensor rods 50a and 50b such that they are movable in the X-axis direction between a protruding position and a retracted position. In other words, the wafer holding plates 21 and the sensor rods 50a and 50b are disposed in opposing directions, back-to-back with respect to the Y-axis rotation driver 362, and may move independently on the X-axis. The sensor rods 50a and 50b are movable in the longitudinal direction (up-down direction or Z-axis direction) of columns 25a to 25c of the boat 25 via the Z-axis direction driver 361.

Thus, the wafer transferrer 19 is capable of mapping the wafers 1 within the cassette 2 by using the fiber sensors 51a and 51b. In addition, the wafer transferrer 19 is capable of mapping the wafers 1 within the boat 25 by using the fiber sensors 51a and 51b. Thus, it is possible to detect a state of the wafer 1 disposed in each slot of the boat 25 before or after processing such as film formation.

### (2) Substrate Processing Step

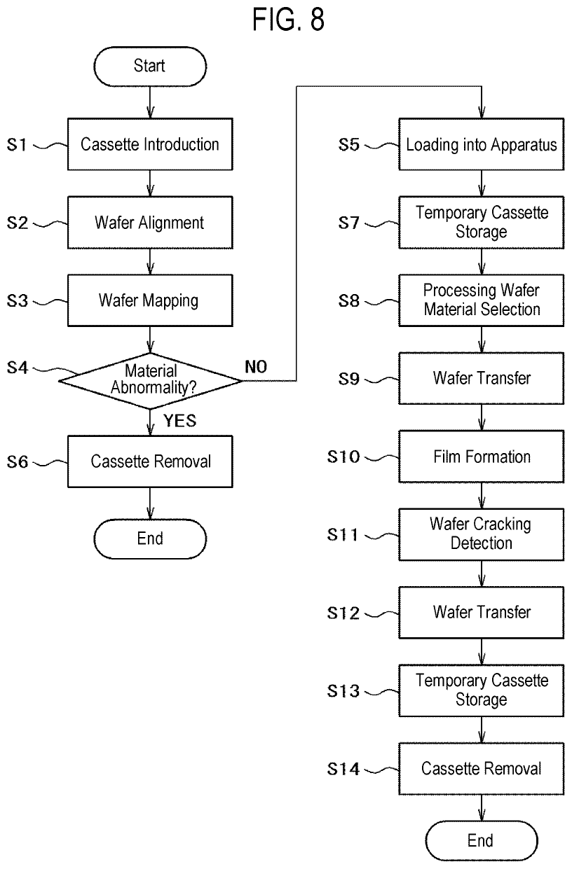

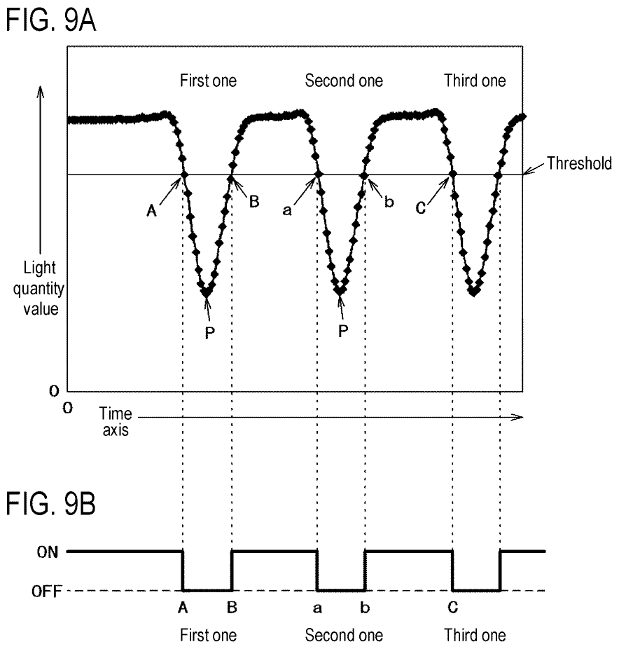

Next, a substrate processing method using the reaction tube 31 of the processing apparatus 10 is described with reference to FIGS. 8 to 9B. Herein, one step in the manufacturing process of semiconductor devices (devices), for example, film formation processing for forming a film on the wafer 1, is described by way of example. In the following description, an operation of each part constituting the processing apparatus 10 is controlled by the main controller 120.

### (Cassette Introduction: S1)

The cassette 2 charged with unprocessed wafers 1 is placed (loaded) onto the cassette stage device 13 of the cassette receiving unit 12 with help of an external transporter (not illustrated) or human operator. The wafers 1 within the cassette 2 are in the vertical state. Further, around this time, information indicating the materials of the wafers 1 stored in the placed cassette 2 (material information) or information indicating the thicknesses of the wafers 1 (thickness information) is given from a higher-level control device or human operator. Further, the strain gauges 108a and 108b measure the weights of the cassette 2 and the wafers 1, which are registered as weight information. Weight data of an empty cassette 2 are acquired in advance and registered as master data.

### (Wafer Alignment: S2)

First, the external receiving stage 47 is lowered to bring the wafers 1 into contact with the roller 142 of the wafer posture aligner, where the wafers 1 are aligned by using the notches or similar features. At this time, the wafers 1 are positioned among the protrusions 112a, 112b, 112c, 112d, and the like of the comb-shaped sensor 111. After that, the external receiving stage 47 is raised.

### (Wafer Mapping: S3)

After operating the first mapping apparatus in the confirmation mode as appropriate, wafer mapping according to the first mode or the second mode is performed while the external receiving stage 47 is lowered. At this time, the wafers 1 within the cassette 2 are in the vertical state.

The discriminator 117 of the first mapping apparatus detects the presence or absence of wafers (the number of wafers) and the material. However, for example, if the transmittance of a SiC wafer is decreased due to film formation, the SiC wafer may be recognized as a Si wafer, and material determination may not be possible. Since weights or thicknesses of a SiC wafer and a Si wafer may differ, it is possible to discriminate between the SiC wafer and the Si wafer by performing at least one selected from the group of weight measurement and thickness measurement. Accordingly, the transmittance, thickness, and weight of the wafer are measured, and final material discrimination is performed based on these combined results.

Discrimination based on weight measurement is described below. A weight of a single wafer is determined by factors such as a size (diameter), thickness, and material (density) thereof. In actual manufacturing environments, there are several wafer types that are used and may be mixed in, each of which possesses a different mass. For example, a case is described where solely two types of wafers, i.e., Si wafers and SiC wafers, are used, each cassette accommodates either Si wafers or SiC wafers, and a weight difference per wafer between Si and SiC is known. In this case, if n Si wafers are mixed in, a total weight differs from that of a cassette with solely SiC wafers by (n×weight difference). Therefore, it is possible to determine whether Si wafers are mixed in by measuring the total weight of the cassette. In addition, more generally, it is possible to determine a combination of wafer types and their respective quantities from the total weight of the cassette. The number of wafers of each type may be treated as a resource allocation problem or a mixed integer programming problem, which is a type of discrete optimization problem, and obtained, for example, by using an algorithm, such as a greedy algorithm.

Description is given of discrimination based on thickness measurement. The thickness of the wafer may be measured by using the laser sensor 101 of the above-described second mapping apparatus. Hereinafter, wafer mapping using the laser sensor 101 is described with reference to FIG. 6. The wafer mapping in the following description is performed under the control of the main controller 120 and the sub-controller 100.

First, the cassette stage device 13 rotates by 90 degrees, thereby rotating the cassette 2 by 90 degrees. The wafer 1 within the cassette 2 is brought into the horizontal state.

Next, as illustrated in FIG. 6, when the wafer 1 is in the horizontal state in the cassette stage device 13, the main controller 120 operates the cassette transporter 17 to move the laser sensor 101 to a position behind the reflector 106 of the cassette stage device 13 (in the X2 direction).

The main controller 120 moves the robot arm 18 to a position slightly below the trigger sensor 104 as appropriate, and instructs the sub-controller 100 to prepare for scanning. Thereafter, the main controller 120 raises the robot arm 18 at a constant speed. The sub-controller 100 turns on light projection of the laser sensor 101, and starts sampling a light reception intensity of the laser sensor 101 at a timing when the trigger sensor 104, such as a dog sensor, detects a passage of a reference position. Since the laser sensor 101 is a reflective sensor that receives retro-reflection from the reflector 106, the light reception intensity (amount of received light) increases at a location where the wafer 1 is present, and decreases at a location where the wafer 1 is absent. The laser sensor 101 acquires this as scan data. In this example, a minimum drive unit, a lifting speed, and a sampling rate of the driver of the cassette transporter 17 are designed such that light reception intensity data is obtained at an interval of 0.05 mm. This may realize a position resolution of 0.05 mm in a height direction.

The main controller 120 performs threshold processing (binarization processing) on the scan data acquired from the sub-controller 100, and extracts, as detection data, a section in which the scan data continuously exceeds a threshold. The detection data corresponds to the thickness of the wafer 1. The threshold used herein is common to any combination of the size and material of the wafer 1. This is because a reflection intensity from the end surface depends relatively little on the size or material of the wafer 1.

The wafer 1 within the cassette 2 is in the horizontal state on the internal receiving stage 46, and in addition to the thickness measurement, the main controller 120 may also measure a reflection intensity from the end surface of the wafer 1 by using the laser sensor 101. A light reception level in a circumferential portion on both sides of the notch is strong, but in the V-shaped notch, the reflected light does not return, resulting in a low light reception level. It is possible to measure a dimension of the notch from this width in the horizontal direction.

### (Material Abnormality Determination: S4)

The main controller 120 manages the materials of the plurality of wafers 1 accommodated in the cassette 2 and loaded in, based on the material information given in step S1. Then, when the cassette 2 accommodating a mixture of multiple different wafers 1 is loaded in, the main controller 120 determines whether processing in the reaction tube 31 may be continued, based on the discrimination result of the material by the first mapping apparatus and others in step S3. For example, the main controller 120 compares the aforementioned material information with the material discriminated by the first mapping apparatus, and determines that there is a material abnormality if there is a discrepancy. The method proceeds to step S5 if the processing may be continued, but proceeds to step S6 if the processing may not be continued based on the determination of a material abnormality. This allows the main controller 120 to perform a control based on a temperature of processing performed in the reaction tube 31 such that the wafers 1 of a type or a use that may not withstand the process temperature are not charged into the reaction tube 31.

For example, a material abnormality is determined based on the process temperature, the wafer material given in step S1, and the wafer material discriminated in step S3. For example, if the wafer material given in step S1 is SiC, the wafer material discriminated in step S3 includes Si, and the process temperature is equal to or higher than the melting point of Si, it is determined to be abnormal, and the method proceeds to step S6. In other cases, it is determined to be normal and the method proceeds to step S5. In addition, if the process temperature is lower than the melting point of Si, it is not determined to be abnormal, and a mixture of SiC wafers and Si wafers is allowed. In other words, the processing may sometimes be continued even if SiC wafers and Si wafers are mixed. The process temperature herein refers to a temperature of the wafers 1 or an internal temperature of the process chamber 32. This is also applied to the following description. In addition, if the material information in step S1 does not match the determination result in step S3, but the determination result in step S3 is sufficiently reliable, it is not determined that there is a material abnormality as long as the processing may be continued using wafers from another cassette. In that case, the mismatched wafer material is regarded as the material of the determination result in step S3.

As described above, there are cases where the first mapping apparatus is not able to perform material determination. In this case, determination is made in combination with other measurement results as described below.

For example, the main controller 120 selects one or more first candidates for the use or the type of each of the wafers 1 from the thickness detected by the laser sensor 101 with reference to the stored specifications (wafer thickness), and selects one or more second candidates for the use or the type of each of the wafers 1 based on the material discriminated by the first mapping apparatus. Then, the main controller 120 identifies one use or one type common to both the first and second candidates as the use or the type of each of the wafers 1. The identification of the use or the type of each of the wafers 1 is completed while the wafers 1 are on the cassette stage device 13.

The main controller 120 may also select one or more third candidates for the use or the type of each of the wafers 1 from the dimension of the notch detected by the laser sensor 101 with reference to the stored specifications (the type or the dimension of the wafer orientation indication shape). Then, the main controller 120 identifies one use or one type common to the above-described first, second, and third candidates as the use or the type of each of the wafers 1.

When there is one or more unidentified wafers 1 with multiple uses or types of the wafers 1 common to the above-described first and second candidates, the main controller 120 performs the following processing. The main controller 120 selects one combination of weights corresponding to a value obtained by subtracting a total weight of the identifies wafers 1 from a total weight detected by the strain gauges 108a and 108b from among possible combinations of weights for the unidentified wafers 1 with reference to the stored specifications (substrate weight). Then, the main controller 120 identifies the use or the type of the unidentified wafers 1 based on a selected result.

### (Cassette Removal: S6)

If a material abnormality is determined in step S4, the corresponding cassette is removed. In other words, the cassette 2 is made removable. Along with this, an alarm or the like is issued to prompt the unloading of the cassette on the cassette stage device 13 to an outside of the housing 11.

(Loading into Apparatus: S5)

The cassette 2 on the cassette stage device 13 is held by the robot arm 18 and is loaded into the apparatus (cassette holding chamber 60) from the cassette receiving unit 12.

### (Temporary Cassette Storage: S7)

Next, the cassette 2 held by the robot arm 18 is transferred by the robot arm 18 to the cassette shelf 15 or the spare cassette shelf 16, where it is temporarily stored.

### (Material Selection of Wafer for Processing: S8)

When certain batch processing is scheduled, the main controller 120 attempts to determine whether it is possible to select the wafers needed for the batch processing from the cassettes stored in the cassette holding chamber 60, prior to actual wafer transfer (S9). The attempt is made using the material information for each wafer managed in S4 or other specifications. For example, when the wafers of multiple materials are stored in the apparatus, the wafer material may be selected according to film formation conditions. A description thereof is omitted since the details are the same as in step S9. If the attempt is successful and a previous batch is completed, the batch processing becomes ready to start.

### (Wafer Transfer: S9)

When certain batch processing starts, the main controller 120 controls the robot arm 18 to sequentially move the cassette 2 from the cassette shelf 15 or the spare cassette shelf 16 to a transfer shelf located opposite the wafer transferrer 19 of the cassette shelf 15. The wafers 1 within the cassette 2 placed on the transfer shelf are sequentially transferred to the boat 25 by the wafer transferrer 19. At this time, the main controller 120 controls the wafer transferrer 19 by referring to a boat MAP, which is map information indicating from which slot of which cassette the wafers need to be transferred for each slot of the boat. Further, the main controller 120 controls the wafer transferrer 19 by referring to thickness data for the wafers 1 acquired in step S4.

When the cassette 2 accommodating a mixture of multiple different wafers 1 is loaded in, the main controller 120 controls the wafer transferrer 19 based on the material discrimination result by the first mapping apparatus such that the wafers 1 of a corresponding material are disposed in each slot of the boat 25 that holds a plurality of wafers 1 within the reaction tube 31. Further, the main controller 120 corrects a height of the wafer holding plate 21 according to the thickness of the wafers 1 being transferred.

Since the thickness varies depending on the wafer type, the wafers 1 are transferred from the cassette 2 to the boat 25 at insertion heights corrected according to the wafer type. When the wafer holding plate 21 holding the wafers 1 is inserted into or withdrawn from the boat 25, the insertion height is corrected according to the thickness of the held wafers 1 so that upper and lower clearances are uniform (maximized). When inserting or withdrawing the wafer holding plate 21, which is not holding the wafers 1, into or from the boat 25, the insertion height is corrected according to a thickness of a side dummy substrate directly below if the side dummy substrate is present in a wafer holding region (slot) directly below.

More specifically, a difference in thickness (thickness difference) between the wafer used during teaching and the wafer used during processing is corrected and managed in operation. During the wafer transfer, the wafer holding plate 21 is positionally corrected such that it moves to a position where clearances between it and the wafers above and below are equally distributed. Due to the wafer thickness difference on support portions of the boat 25, lower surfaces of the wafers are uniformly maintained, but upper surfaces of the wafers are shifted by the thickness difference. Half of the thickness difference of the transferred wafers is corrected with respect to the wafer thickness used during teaching (management), so that the upper and lower clearances are equalized. By registering the wafer thickness used during teaching, it is possible to handle the operation or mixing of wafers with different thicknesses by using corrected calculation values without re-teaching.

### (Film Formation: S10)

Next, the boat 25 is loaded into the reaction tube 31 by the boat elevator 22. Once the boat 25 is loaded into the reaction tube 31, an atmosphere within the process chamber 32 is controlled such that an internal pressure of the process chamber 32 is set to a predetermined value. Further, the process chamber 32 is controlled to a predetermined temperature by a heater, and, for example, a precursor gas and a reactant gas are supplied into the process chamber 32 to form a film on the wafer 1. After film formation, the boat 25 is removed from the reaction tube 31 by the boat elevator 22.

### (Wafer Detection: S11)

Next, wafer cracking detection performed by wafer mapping using the fiber sensors 51a and 51b installed at the wafer transferrer 19 is described with reference to FIGS. 9A and 9B.

When heated within the reaction tube 31, or when cooled after being removed from the reaction tube 31, thermal stress may cause the wafer 1 to crack, warp, or experience other abnormalities. Further, if the wafer 1 cracks, a part of the wafer 1 may remain held in the holding grooves of the boat 25 while the other part falls out of the holding grooves, or the wafer 1 may completely fall out of the holding grooves, resulting in an abnormal state. In addition, if the wafer 1 is in a normal state, one wafer 1 is supported in parallel by three holding grooves provided in the boat 25.

First, acquisition of master data for detecting the state of the wafer 1 is described.

The main controller 120 moves the fiber sensors 51a and 51b from bottom to top by using the Z-axis direction driver 361 of the wafer transferrer 19 in a state where the wafer 1 is placed in advance on the holding grooves of the boat 25. Then, the main controller 120 acquires waveform data (placement waveform data) for each slot serving as the holding groove, as illustrated in FIG. 9A, and stores the data in the main memory 122 in association with the slot (for each slot number). Further, the main controller 120 acquires a wafer lower reference value (micro-lower), a wafer upper reference value (micro-upper), and a peak position from each placement waveform data, and stores each as master data in the main memory 122. Herein, the wafer lower reference value (micro-lower) is a position where a light quantity decreases and crosses a threshold, and represents a lower end of the wafer 1. The wafer upper reference value (micro-upper) is a position where the light quantity increases and crosses the threshold, and represents an upper end of the wafer 1. The peak position is a position where the light quantity is the smallest, and indicates a center of the wafer. In FIG. 9A, points A and a indicate the micro-lower, points B and b indicate the micro-upper, and points P and p indicate the peak positions. A distance between A-B or a-b corresponds to the wafer thickness. In addition, in practice, instead of the wafer 1 serving as a product substrate, a monitor wafer used for substrate quality checking or a new dummy wafer may be used to acquire the master data.

Next, wafer cracking detection is described.

The main controller 120 moves the fiber sensors 51a and 51b in the up-down direction by using the Z-axis direction driver 361 of the wafer transferrer 19 and detects the wafers 1 on the boat 25, similar to when acquiring the master data. Then, the main controller 120 acquires waveform data (detection waveform data) as illustrated in FIG. 9A, and acquires micro-lower, micro-upper, and peak positions from the detection waveform data. Due to cracking or warping of the wafer 1 described above, a discrepancy may occur between the micro-lower, micro-upper, and peak positions obtained from the detection waveform data and the micro-lower, micro-upper, and peak positions from the master data. Therefore, the wafer 1 in the holding grooves for which this discrepancy exceeds an allowable value is detected as a cracked wafer.

The discrepancy exceeding the allowable value occurs between the detection data and the master data also when a part of the wafer 1 falls from the holding grooves of the boat 25 due to the above-described cracking of the wafer 1. The wafer 1 in the holding grooves where this discrepancy occurs is determined to be in an abnormal transfer state. Similarly, when the wafer 1 is completely fallen out of the holding grooves due to cracks or similar issues and is thus absent from the holding grooves where it needs to be held, this results in no light blockage and may be detected as a wafer loss.

The micro-lower (points A and a), micro-upper (points B and b), and peak positions (points P and p) are used in determining the cracking detection. These are affected by the wafer thickness. The micro-lower is not affected by the wafer thickness, but the peak and micro-upper values vary with the wafer thickness. Therefore, the allowable value for the cracking detection is changed accordingly.

The main controller 120 determines the state of the wafer 1 based on the results of the fiber sensors 51a and 51b by using a reference value corrected according to the thickness of the wafer 1 being transferred.

For example, a wafer thickness (t) at a time of master data acquisition for the cracking detection may sometimes differ from a thickness (T) of a detection target wafer measured in step S3. In this case, the allowable value for the cracking detection is corrected as follows.

$$Micro - lower : Correction \qquad ( 0 )$$

$$Peak position : ( t - T ) / 2 \qquad ( 1 )$$

$$Micro - upper : ( t - T ) \qquad ( 2 )$$

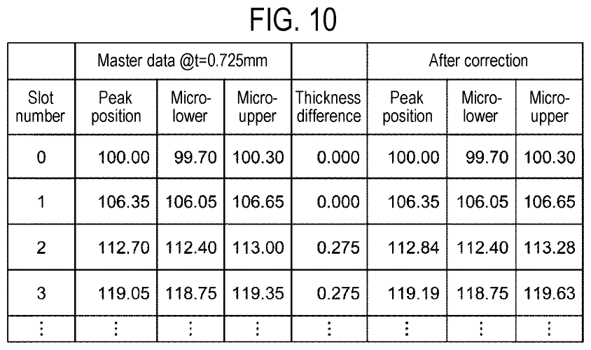

A correction example is described with reference to FIG. 10.

For slot numbers “0” and “1”, there is no difference (thickness difference) between the wafer thickness of master data (t=0.725 mm) and the detection target wafer thickness. Therefore, no correction is made. For slot numbers “2” and “3”, the thickness difference (t−T) is 0.275 mm. Therefore, the peak position and micro-upper are corrected according to Equations (1) and (2), respectively.

For the wafer thickness (management) at the time of the master data acquisition, the micro-lower (lower surface position) is not corrected, the micro-upper (upper surface position) is corrected by the thickness difference, and the peak position (center position) is corrected by half the thickness difference. By registering the wafer thickness used at the time of the master data acquisition for the cracking detection, it is possible to handle the operation or mixing of wafers with different thicknesses by using corrected calculation values without re-acquiring master data.

### (Wafer Transfer: S12)

Next, the processed wafers 1 within the boat 25 are transferred sequentially into the cassette 2 on the transfer shelf by the wafer transferrer 19. Since the wafer thickness varies depending on the wafer type, the wafers 1 are transferred from the boat 25 to the cassette 2 at an insertion height corrected according to the wafer type.

### (Temporary Cassette Storage: S13)

Next, the cassette 2 on the transfer shelf is sequentially moved to the cassette shelf 15 or the spare cassette shelf 16 by the robot arm 18, and is temporarily stored.

### (Cassette Removal: S14)

When the cassette 2 is to be unloaded from the processing apparatus 10, the cassette 2 is transferred by the robot arm 18 from the cassette shelf 15 or the spare cassette shelf 16 to the cassette stage device 13 of the cassette receiving unit 12. Next, the cassette 2 is rotated 90 degrees by the cassette stage device 13 so that the access opening faces upward.

According to the present embodiments, one or more of the following effects are obtained.

(a) It is possible to discriminate the materials of the wafers by using a single set of the multiple light emitters and the multiple light receivers (i.e., one transmission-type comb-shaped sensor).

(b) It is possible to detect multiple materials with a single operation of relative movement between the wafer and the sensor since a simultaneous operation or an alternative operation of the first and second modes is possible.

(c) Switching from the first mode to the second mode is possible since a selection signal may be output from the controller or the discriminator.

(d) The determiner performs the confirmation mode to verify whether the reference light reception intensity is appropriate, making it possible to enhance accuracy of the thresholds for making determinations.

(e) It is possible to determine the materials when a cassette accommodating a mixture of multiple different wafers is loaded, allowing the apparatus to determine a cassette introduction error.

(f) It is possible to issue an alarm if there is a discrepancy by comparing the material information of multiple wafers within the cassette, either acquired from a higher-level device or registered in advance, with the material discriminated by the first mapping apparatus. This makes it possible to notify the operator of a cassette introduction error.

(g) It is possible to store the specifications including the material and the thickness of wafers for each use or each type of the wafers since the use or the type of the wafers accommodated in the loading cassette may be acquired from a higher-level device or registered in advance. This makes it possible to optimize the clearances for the wafer transport.

(h) It is possible to store the specifications including the material and the thickness of wafers for each use or each type of the wafers since the use or the type of the wafers accommodated in the loading cassette may be acquired from a higher-level device or registered in advance. This makes it possible to improve reliability of the cracking detection.

(i) Once the material discrimination is completed on the cassette stage device, it is possible to perform a control according to the process temperature such that wafers of a use or a type that may not withstand the temperature of processing performed within the reaction tube are not loaded into the reaction tube. This allows for efficient apparatus operation even when materials are mixed.

(j) It is possible to discriminate the material on the cassette stage device. This makes it possible to allocate wafers of a corresponding material in each slot of the boat based on the material discrimination result from the mapping apparatus when a cassette accommodating a mixture of multiple different wafers is loaded.

(k) It is possible to optimize the clearances for the wafer transport since it is possible to correct the height of the wafer holding plate according to the thickness of the wafer to be transferred.

(l) It is possible to improve the reliability of the cracking detection since the state of the wafer is determined from the results of the mapping sensors by using a reference value corrected according to the thickness of the wafer to be transferred.

(m) It is not needed to perform re-teaching and re-acquisition of the master data unless the boat is changed even if wafers of different thicknesses are mixed in the same apparatus since the state of the wafer is determined from the results of the mapping sensors by using a reference value corrected according to the thickness of the wafer to be transferred.

(n) It is not needed to regulate the allowable value for the cracking detection based on the wafer thickness since the state of the wafer is determined from the results of the mapping sensors by using a reference value corrected according to the thickness of the wafer to be transferred.

(o) The use or the type of each of the wafers is identified based on the thickness detected by the laser sensor and the material discriminated by the first mapping apparatus. This makes it possible to discriminate the wafer material that may not be discriminated by the first mapping apparatus.

(p) The use or the type of each of the wafers is identified based on the notch dimension detected by the laser sensor, the thickness detected by the laser sensor, and the material discriminated by the first mapping apparatus. This makes it possible to discriminate the wafer material that may not be discriminated by material discriminated by the first mapping apparatus and the thickness detected by the laser sensor.

(q) Since the material discrimination is possible using mapping information (number of wafers) on the cassette stage device and wafer weight information (including cassette weight), material discrimination accuracy may be improved by using the comb-shaped sensor information and the weight information when the wafer transmittance changes due to film formation.

(r) It is possible to complete the identification of the use or the type of each of the wafers while the wafers are still on the cassette stage device since the laser sensor is configured to be capable of detecting the thickness of the plurality of wafers accommodated in the cassette on the cassette stage device.

(s) It is possible to complete the identification of the use or the type of each of the wafers while the wafers are still on the cassette stage device since the strain gauge is disposed to bear the entire weight of the cassette accommodating the wafers on the cassette stage device.

In the above-described embodiments, an example of a batch-type substrate processing apparatus that processes multiple substrates at once is described. The present disclosure is not limited to the above-described embodiments, and may also be applied, for example, to a single-wafer substrate processing apparatus capable of processing one or several substrates at once. The single-wafer type apparatus may not include a cassette shelf or a cassette transporter, but mapping involving material discrimination as disclosed in the present disclosure may still be performed by using a substrate transferrer or other mapping tools within a load port or a vacuum load lock chamber. Further, in the above-described embodiments, an example of forming a film by using a substrate processing apparatus equipped with a hot wall type process furnace is described. The present disclosure is not limited to the above-described embodiments, and may be suitably applied to a substrate processing apparatus with a cold wall type process furnace as well.

Even when using such a substrate processing apparatus, it is possible to perform each processing using the same processing procedures and processing conditions as in the above-described embodiments, and to achieve the same effects as the above-described embodiments.

According to the present disclosure, it is possible to discriminate materials of wafers.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A mapping apparatus comprising:
a plurality of light emitters arranged to be capable of emitting reference light onto each of a plurality of substrates arranged at a predetermined interval;
a plurality of light receivers disposed to face the plurality of light emitters, each of the plurality of light receivers being capable of detecting light transmitted through a corresponding substrate among the plurality of substrates;
a driver configured to relatively move the plurality of substrates so that the plurality of substrates pass through a plurality of optical axes connecting the plurality of light emitters and the corresponding plurality of light receivers respectively;
a determiner configured to perform a predetermined determination based on a light reception intensity of each of the plurality of light receivers; and
a discriminator configured to discriminate a material of each of the plurality of substrates based on a determination result from the determiner.

2. The mapping apparatus of claim 1,
wherein the determiner is configured to be capable of performing a simultaneous operation or an alternative operation of a first mode in which the determiner determines whether a transparent substrate passed through each optical axis based on a change in the light reception intensity of each of the plurality of light receivers when each end of the plurality of substrates passed through the plurality of optical axes and a second mode in which the determiner determines whether a non-transmissive substrate is present on each optical axis based on the light reception intensity of each of the plurality of light receivers when the plurality of substrates are present on the plurality of optical axes, and
wherein the discriminator performs discrimination of presence or absence of each of the plurality of substrates and of the material of each of the plurality of substrates based on a combination of determination results in the first mode and the second mode.

3. The mapping apparatus of claim 2, wherein, in a state where the plurality of optical axes intersect the plurality of substrates respectively, the determiner is switched from the first mode to the second mode, and the discrimination of the presence or absence of each of the plurality of substrates and of the material of each of the plurality of substrates is completed through a single reciprocating movement by the driver.

4. The mapping apparatus of claim 1, further comprising a comb-shaped frame configured to integrally accommodate the plurality of light emitters and the plurality of light receivers.

5. The mapping apparatus of claim 2, wherein the determiner is configured to enable input of a selection signal for selection of one of the first mode and the second mode from a controller for the driver or from the discriminator.

6. The mapping apparatus of claim 2, wherein the determiner includes a confirmation mode in which the determiner acquires, as a reference light reception intensity, the light reception intensity of each of the plurality of light receivers in a state where no substrate is present on the plurality of optical axes, and checks whether the reference light reception intensity is appropriate by checking whether the reference light reception intensity is greater than a prescribed threshold,
wherein in the first mode, the determiner determines that a substrate is passed if a maximum decrease in the light reception intensity is greater than a value obtained by multiplying the reference light reception intensity by a first coefficient less than 1, and
wherein in the second mode, the determiner determines that a substrate is present if the light reception intensity is lower than a value obtained by multiplying the reference light reception intensity by a second coefficient less than 1.

7. A substrate processing apparatus comprising:
a load port including the mapping apparatus of claim 1 and configured to load and unload a cassette capable of accommodating a plurality of substrates;
a process container configured to process a substrate; and
a main controller configured to be capable of managing a material of each of the plurality of substrates accommodated in the cassette and loaded in, and continuing processing in the process container based on a material discrimination result by the mapping apparatus when a cassette accommodating a mixture of a plurality of different substrates is loaded.

8. The substrate processing apparatus of claim 7, wherein the mapping apparatus performs discrimination of presence or absence of each of the plurality of substrates accommodated in the cassette and of the material of each of the plurality of substrates accommodated in the cassette, which is placed on the load port and is yet to be loaded inside the substrate processing apparatus, and
wherein the main controller is configured to be capable of issuing an alarm when there is a discrepancy by comparing material information of the plurality of substrates within the cassette, either acquired from a higher-level apparatus or registered in advance, with a material discriminated by the mapping apparatus.

9. The substrate processing apparatus of claim 7, wherein the main controller is configured to store a specification including a material and a thickness for each use or each type of a substrate, and to be capable of acquiring from a higher-level apparatus or pre-registering a use or a type of each of the plurality of substrates accommodated in the cassette to be loaded into the substrate processing apparatus.

10. The substrate processing apparatus of claim 7, wherein the main controller is configured to be capable of performing a control based on a temperature of the processing performed in the process container such that a substrate of a type or a use that is unable to withstand the temperature of the processing is not charged into the process container.

11. The substrate processing apparatus of claim 7, wherein the main controller is configured to be capable of controlling a transferrer such that a substrate of a corresponding material is disposed in each slot of a boat that holds a plurality of substrates within the process container based on the material discrimination result by the mapping apparatus when the cassette accommodating the mixture of the plurality of different substrates is loaded.

12. The substrate processing apparatus of claim 9, further comprising a transferrer configured to hold a substrate on a fork and transfer the substrate to a boat or the cassette,
wherein the main controller is configured to be capable of correcting a height of the fork according to a thickness of the substrate being transferred.

13. The substrate processing apparatus of claim 9, further comprising a mapping sensor configured to detect a state of a substrate disposed in each slot of a boat that holds a plurality of substrates within the process container, before or after the processing,
wherein the main controller is configured to be capable of determining the state of the substrate based on a mapping result from the mapping sensor by using a reference value corrected according to a thickness of the substrate being transferred.

14. The substrate processing apparatus of claim 9, further comprising a thickness sensor capable of detecting a thickness of each of the plurality of substrates accommodated in the cassette,
wherein the main controller is configured to be capable of:
selecting one or more first candidates for the use or the type of each of the plurality of substrates from the thickness detected by the thickness sensor with reference to the stored specification;
selecting one or more second candidates for the use or the type of each of the plurality of substrates from a material discriminated by the mapping apparatus; and
identifying, as the use or the type of each of the plurality of substrates, one use or one type common to both the first candidates and the second candidates.

15. The substrate processing apparatus of claim 14, further comprising a notch sensor capable of detecting an orientation indication shape of each of the plurality of substrates accommodated in the cassette,
wherein the specification includes a type or a dimension of the orientation indication shape of a substrate, and
wherein the main controller is configured to be capable of:
selecting one or more third candidates for the use or the type of each of the plurality of substrates from a thickness detected by the notch sensor with reference to the stored specification; and
identifying, as the use or the type of each of the plurality of substrates, one use or one type common to the first candidates, the second candidates, and the third candidates.

16. The substrate processing apparatus of claim 14, further comprising a strain gauge capable of detecting a total weight of the plurality of substrates accommodated in the cassette,
wherein the specification includes a substrate weight, and
wherein, when one or more unidentified substrates with a plurality of uses or types common to the first candidates and the second candidates exist, the main controller is configured to be capable of:
selecting one combination of weights corresponding to a value obtained by subtracting a total weight of identified substrates from the total weight detected by the strain gauge from among possible combinations of weights for the one or more unidentified substrates with reference to the stored specification; and
identifying a use or a type of each of the unidentified substrates based on a selected result.

17. The substrate processing apparatus of claim 14, wherein the thickness sensor is configured to be capable of detecting the thickness of each of the plurality of substrates accommodated in the cassette on a stage, and the identifying the use or the type of each of the plurality of substrates is completed while the plurality of substrates are on the stage.

18. A mapping method comprising:
(a) emitting reference light from a plurality of light emitters onto each of a plurality of substrates arranged at a predetermined interval;
(b) detecting light by a plurality of light receivers disposed to face the plurality of light emitters, each of the plurality of light receivers being capable of detecting light transmitted through a corresponding substrate among the plurality of substrates;
(c) relatively moving the plurality of substrates by a driver so that the plurality of substrates pass through a plurality of optical axes connecting the plurality of light emitters and the corresponding plurality of light receivers respectively;
(d) performing a predetermined determination based on a light reception intensity of each of the plurality of light receivers; and
(e) discriminating a material of each of the plurality of substrates based on the predetermined determination.

19. A method of manufacturing a semiconductor device, comprising processing a substrate mapped by the mapping method of claim 18.

20. A non-transitory computer-readable recording medium storing a program that causes, by a computer, a substrate processing apparatus to perform a process comprising:
(a) emitting reference light from a plurality of light emitters onto each of a plurality of substrates arranged at a predetermined interval;
(b) detecting light by a plurality of light receivers disposed to face the plurality of light emitters, each of the plurality of light receivers being capable of detecting light transmitted through a corresponding substrate among the plurality of substrates;
(c) relatively moving the plurality of substrates by a driver so that the plurality of substrates pass through a plurality of optical axes connecting the plurality of light emitters and the corresponding plurality of light receivers respectively;
(d) performing a predetermined determination based on a light reception intensity of each of the plurality of light receivers; and
(e) discriminating a material of each of the plurality of substrates based on the predetermined determination.
